(19) United States
(12) Patent Application Publication
(10) Pub. No.: US 2025/0237622 A1
(43) Pub. Date: Jul. 24, 2025

(54) DEVICE FOR MEASURING MAGNETIC CHARACTERISTICS

(71) Applicant: Samsung Electronics Co., Ltd., Suwon-si (KR)

(72) Inventors: Ingi Kim, Suwon-si (KR); Shinji Ueyama, Suwon-si (KR)

(21) Appl. No.: 19/011,724

(22) Filed: Jan. 7, 2025

(30) Foreign Application Priority Data
Jan. 19, 2024 (JP) 2024-006635
Aug. 23, 2024 (KR) 10-2024-0113715

(51) Int. Cl. G01N 24/10; G01N 21/21

(52) U.S. Cl. CPC G01N 24/10; G01N 21/21

(57) ABSTRACT

A device for measuring magnetic characteristics, includes a first magnetic field generator generating a gradient magnetic field having a different magnetic field depending on a position; a second magnetic field generator generating a high-frequency magnetic field that is time-based variable; a first actuator moving the second magnetic field generator; a mount mounting a test object; a second actuator moving the mount; and a measuring unit measuring the magnetic characteristics of the test object moving in the gradient magnetic field.

### CROSS-REFERENCE TO RELATED APPLICATION(S)

This application claims benefit of priority to Japanese Patent Application No. 2024-006635 filed on Jan. 19, 2024 and Korean Patent Application No. 10-2024-0113715 filed on Aug. 23, 2024 in the Korean Intellectual Property Office, the disclosures of which are incorporated herein by reference in its entirety.

### BACKGROUND

The present inventive concept relates to a device for measuring magnetic characteristics, and for example, to a device for measuring magnetic characteristics that examines the magnetic characteristics of a magnetoresistive memory element at high speed and high sensitivity.

A semiconductor memory element, known as a magnetoresistive memory (magnetoresistive random access memory (MRAM)) may be a non-volatile memory including a magnetic tunnel junction (MTJ) element as a component. In a semiconductor production line, before completion of a magnetoresistive memory device (MRAM device), early examination of abnormalities in a magnetoresistive memory formed on a wafer may be important for improving yield in production of the magnetoresistive memory device. In order to examine a magnetoresistive memory device before completion thereof, it is often necessary to grasp magnetic characteristics as well as a non-destructive external inspection using an optical microscope, an electron beam, or the like.

As a high-speed measuring means of magnetic characteristics, optical measurement utilizing a magneto-optical effect called a magneto-optical Kerr effect (MOKE) has been known. According to such a method, an external magnetic field may be applied to each magnetoresistive memory in a magnetoresistive memory device, and magnetic field strength may be changed, and a magnetic hysteresis loop at a measurement point may be obtained by a change amount in polarization in reflected light. However, since such an optical measurement requires applying an external magnetic field to each measurement point to obtain the magnetic hysteresis loop, a measurement time of 10 to 30 seconds is required.

In addition, as described in non-patent document 1, an analysis method called ferromagnetic resonance (FMR) has been also known as a means of measuring magnetic characteristics.

In this method, a magnetic field may be generated from microwaves generated by an AC current in a static magnetic field of about 0 to 1 T. Then, this method obtains a frequency at which ferromagnetic resonance of a magnetization vector undergoing a precessional motion occurs for each value of the static magnetic field. Accordingly, in this method, an anisotropic magnetic field (Hk) and a damping coefficient (a), which may be important characteristics of a magnetoresistive memory, may be measured.

### PRIOR ART DOCUMENTS

### Patent Document

(Patent Document 1) Specification of US Patent Publication No. 2018/0267128
(Patent Document 2) Specification of US Patent Publication No. 2019/0049514
(Patent Document 3) Japanese Patent Publication No. 2022-072599
(Patent Document 4) Japanese Patent Publication No. 2023-063748 Non-Patent Document
(Non-Patent Document 1) Magnetic tunnel junctions with perpendicular easy axis at junction diameter of less than 20 nm”, Hideo Sato et al., Jpn. J. Appl. Phys. 56, 0802A6 (2017)

Each of the above-mentioned patent and non-patent documents is herein incorporated by reference in its entirety.

### SUMMARY

However, since FMR may apply a microwave magnetic field and a waveguide to a measurement target, it is typically necessary to sweep a static magnetic field and a frequency of an AC current at a single point of measurement. For this purpose, there may be a problem that a measurement time period takes more than a few minutes.

The present inventive concept was conceived of to address these issues, and one purpose thereof is to provide a device for measuring magnetic characteristics that may shorten the measurement time period.

According to an aspect of the present inventive concept, a device for measuring magnetic characteristics includes a first magnetic field generator configured to generate a gradient magnetic field having a different magnetic field depending on a position; a second magnetic field generator configured to generate a high-frequency magnetic field that is time-varying; a first actuator configured to move the second magnetic field generator; a mount configured to support a test object mounted thereon; a second actuator configured to move the mount; and a measuring unit configured to measure magnetic characteristics of the test object moving in the gradient magnetic field.

The device may further include a light source generating light; a polarizer converting the generated light into linearly polarized light; an objective lens focusing the light on the test object; a non-polarizing beam splitter separating the light; an analyzer detecting a rotational component in the linearly polarized light of the light; and a line sensor acquiring a scanned image in which the light is scanned on the test object, wherein the device may measure the magnetic characteristics and may also measure a polarization state of the light.

The device may execute, before measuring the test object in the high-frequency magnetic field, a preliminary measurement measuring, in advance, a relationship between a frequency and characteristics of the magnetic field in a predetermined position, and main measurement measuring the magnetic characteristics in the frequency and the magnetic field, to be measured.

The device may further include a controller controlling the first magnetic field generator, the second magnetic field generator, the first actuator, and the second actuator, wherein the controller may execute a first measurement mode in which the magnetic characteristics of the test object is measured by the measuring unit while moving the second magnetic field generator with the first actuator, and moving the mount with the second actuator; and a second measurement mode in which the magnetic characteristics of the test object is measured by the measuring unit while fixing a position of the second magnetic field generator, and moving the mount with the second actuator.

In the device, the controller may further execute a mode in which a resonance frequency of the test object is measured based on the magnetic characteristics of the test object measured by the first measurement mode, and in the second measurement mode, the magnetic characteristics of the test object may be measured in a frequency range including the resonance frequency.

In the device, the second magnetic field generator may include a slit disposed to conduct an optical path between the objective lens and the test object.

In the device, the first magnetic field generator may include two or more magnet units, wherein an optical path between the objective lens and the test object may be disposed between the two or more magnet units.

In the device, the gradient magnetic field may be a static magnetic field.

In the device, measurement of the magnetic characteristics is performed under atmospheric conditions.

The device may further include a temperature controller controlling a temperature of the test object.

The device may further include a third actuator moving the first magnetic field generator.

In the device, the controller may be configured to move the second magnetic field generator together with the test object with respect to the first magnetic field generator in the first measurement mode, and the test object with respect to the second magnetic field generator and the first magnetic field generator in the second measurement mode.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a view illustrating a device for measuring magnetic characteristics according to an embodiment.

FIG. 2 is a view illustrating a portion of a device for measuring magnetic characteristics according to an embodiment.

FIG. 3 is a plan view illustrating a magnetic field generating unit in a device for measuring magnetic characteristics according to an embodiment.

FIG. 4 is a cross-sectional view illustrating a magnetic field generating unit in a device for measuring magnetic characteristics according to an embodiment, and illustrates a cross-section of FIG. 3, taken along line IV-IV.

FIG. 5 is a graph illustrating a magnetic field component in a Z-axis direction of a magnetic force line on a measurement surface in a device for measuring magnetic characteristics according to an embodiment, wherein a horizontal axis represents a position in an X-axis direction on the measurement surface, and a vertical axis represents the magnetic field component in the Z-axis direction of the magnetic force line on the measurement surface.

FIG. 6 is a plan view illustrating a magnetic field generating unit in a device for measuring magnetic characteristics according to an embodiment.

FIG. 7 is a plan view illustrating a stage surface of a stage and a wafer in a device for measuring magnetic characteristics according to an embodiment.

FIG. 8 is a flow chart illustrating a method for measuring magnetic characteristics using a device for measuring magnetic characteristics according to an embodiment.

FIG. 9 is a flow chart illustrating preliminary measurement in a method for measuring magnetic characteristics using a device for measuring magnetic characteristics according to an embodiment.

FIG. 10 is a cross-sectional view illustrating a positional relationship between a wafer and a magnetic field generating unit in preliminary measurement in a method for measuring magnetic characteristics using a device for measuring magnetic characteristics according to an embodiment.

FIG. 11 is a graph illustrating magnetic characteristics acquired by a measuring unit in preliminary measurement in a method for measuring magnetic characteristics using a device for measuring magnetic characteristics according to an embodiment, wherein a horizontal axis represents a position corresponding to a gradient magnetic field, and a vertical axis represents a frequency.

FIG. 12 is a graph illustrating a resonance frequency in each magnetic field in a device for measuring magnetic characteristics according to an embodiment, wherein a horizontal axis represents a frequency and a vertical axis represents an absorption amount.

FIG. 13 is a graph illustrating a relationship between a resonance frequency and a magnetic field in a device for measuring magnetic characteristics according to an embodiment, wherein a horizontal axis represents the magnetic field and a vertical axis represents a resonance frequency.

FIG. 14 is a graph illustrating a relationship between a resonance frequency width and a magnetic field in a device for measuring magnetic characteristics according to an embodiment, wherein a horizontal axis represents the magnetic field and a vertical axis represents a resonance frequency width.

FIG. 15 is a flow chart illustrating main measurement in a method for measuring magnetic characteristics using a device for measuring magnetic characteristics according to an embodiment.

FIG. 16 is a cross-sectional view illustrating a positional relationship between a wafer and a magnetic field generating unit in main measurement in a method for measuring magnetic characteristics using a device for measuring magnetic characteristics according to an embodiment.

FIG. 17 is a graph illustrating magnetic characteristics acquired by a measuring unit in main measurement in a method for measuring magnetic characteristics using a device for measuring magnetic characteristics according to an embodiment, wherein a horizontal axis represents a position corresponding to a gradient magnetic field, and a vertical axis represents a frequency.

FIG. 18 is a graph illustrating a resonance frequency in each magnetic field in a device for measuring magnetic characteristics according to an embodiment, wherein a horizontal axis represents a frequency and a vertical axis represents an absorption amount.

FIG. 19 is a sequence diagram illustrating a method for measuring magnetic characteristics of a die included in a wafer according to an embodiment, wherein a horizontal axis represents time, and a vertical axis represents a current of an electromagnet, an inspection table, a movement direction of the wafer, an inspection period of the die, an image capture clock of a TDI, and a sweep pulse from a frequency (fres−fm) to a frequency (fres+fp).

FIG. 20 is an image diagram illustrating a region on a measurement surface detected by a plurality of line sensors in a device for measuring magnetic characteristics according to an embodiment.

FIG. 21 is a graph illustrating a magnetic field component in a Z-axis direction on a measurement surface in a device for measuring magnetic characteristics according to an embodiment, wherein a horizontal axis represents a position in an X-axis direction on the measurement surface, and a vertical axis represents the magnetic field component in the Z-axis direction on the measurement surface.

FIG. 22 is a graph illustrating a Kerr rotation angle on a measurement surface in a device for measuring magnetic characteristics according to an embodiment, wherein a horizontal axis represents a magnetic field component in a Z-axis direction of an external magnetic field, and a vertical axis represents the Kerr rotation angle.

FIG. 23 is a cross-sectional view illustrating a stage and a magnetic field generating unit in a device for measuring magnetic characteristics according to an embodiment.

FIG. 24 is a perspective view illustrating a stage and a magnetic field generating unit in a device for measuring magnetic characteristics according to an embodiment.

FIG. 25 is a plan view illustrating arrangement of a stage, a magnet, and a line sensor in a device for measuring magnetic characteristics according to an embodiment.

FIG. 26 is a graph illustrating a magnetic field component in a Z-axis direction on a measurement surface in a device for measuring magnetic characteristics according to an embodiment, wherein a horizontal axis represents a position in a Y-axis direction on the measurement surface, and a vertical axis represents the magnetic field component in the Z-axis direction in the measurement surface.

FIG. 27 is a graph illustrating a Kerr rotation angle on a measurement surface in a device for measuring magnetic characteristics according to an embodiment, wherein a horizontal axis represents a magnetic field component in a Z-axis direction of an external magnetic field, and a vertical axis represents the Kerr rotation angle.

FIG. 28 is a plan view illustrating arrangement of a stage, a magnet, and a line sensor in a device for measuring magnetic characteristics according to an embodiment.

FIG. 29 is a graph illustrating a magnetic field component in a Z-axis direction on a measurement surface in a device for measuring magnetic characteristics according to an embodiment, wherein a horizontal axis represents a position in a measurement region expressed as an angle around a rotation axis, and a vertical axis represents the magnetic field component in the Z-axis direction in the measurement surface.

FIG. 30 is a graph illustrating a Kerr rotation angle on a measurement surface in a device for measuring magnetic characteristics according to an embodiment, wherein a horizontal axis represents a magnetic field component in a Z-axis direction of an external magnetic field, and a vertical axis represents the Kerr rotation angle.

FIG. 31 is a plan view illustrating arrangement of a stage, a magnet, and a line sensor in a device for measuring magnetic characteristics according to an embodiment.

FIG. 32 is a graph illustrating a magnetic field component in a Z-axis direction on a measurement surface in a device for measuring magnetic characteristics according to an embodiment, wherein a horizontal axis represents a position in a measurement region expressed as an angle around a rotation axis, and a vertical axis represents the magnetic field component in the Z-axis direction in the measurement surface.

FIG. 33 is a graph illustrating a Kerr rotation angle on a measurement surface in a device for measuring magnetic characteristics according to an embodiment, wherein a horizontal axis represents a magnetic field component in a Z-axis direction of an external magnetic field, and a vertical axis represents the Kerr rotation angle.

### DETAILED DESCRIPTION

Hereinafter, embodiments will be described with reference to the attached drawings as follows.

### Embodiment 1

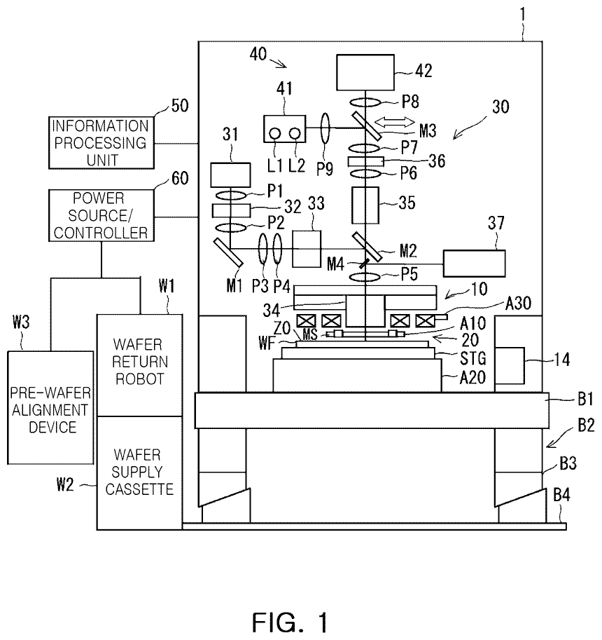

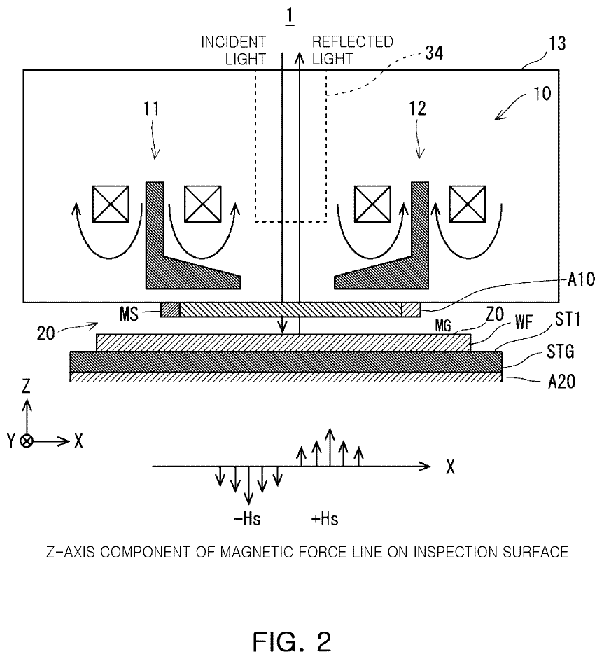

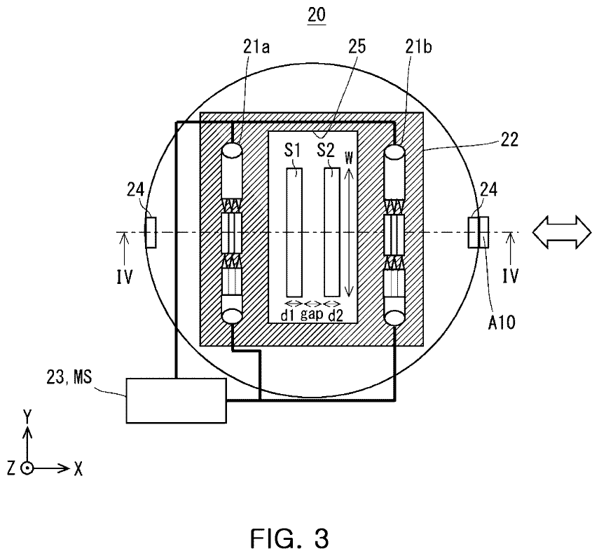

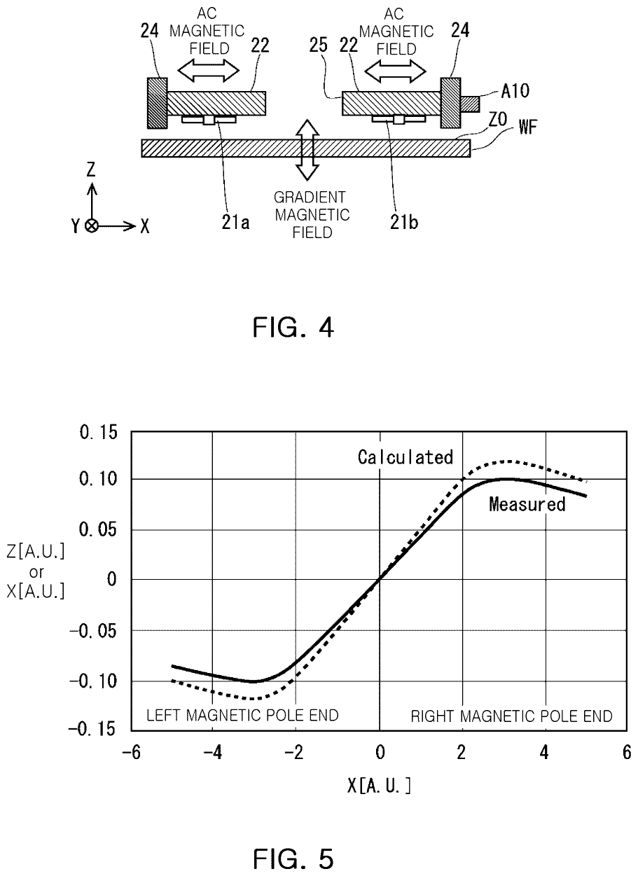

FIG. 1 is a configuration diagram illustrating a device 1 for measuring magnetic characteristics according to an embodiment. FIG. 2 is a configuration diagram illustrating a main portion of a device 1 for measuring magnetic characteristics according to an embodiment. FIG. 3 is a plan view illustrating a magnetic field generating unit 20 in a device 1 for measuring magnetic characteristics according to an embodiment. FIG. 4 is a cross-sectional view illustrating a magnetic field generating unit 20 in a device 1 for measuring magnetic characteristics according to an embodiment, and illustrates a cross-section of FIG. 3, taken along line IV-IV.

As illustrated in FIGS. 1 to 4, a device 1 for measuring magnetic characteristics may include a device (W1 to W3) for returning a wafer WF as a measurement target, a base (B1 to B4) of the device 1, a magnetic field generating unit 10, a magnetic field generating unit 20, an actuator A10, an actuator A20, a stage STG, a measuring unit MS, an optical system 30, a detector 40, an information processing unit 50, and a power source/controller 60. In addition to functioning as a wafer chuck for holding the wafer WF, the stage STG may also have a heater for controlling a temperature of the wafer WF. The heater may be a coil or other induction or wire-type heater, or may also be a light-based heater, such as a laser for radiating light onto a surface of the wafer WF as a measurement target. A test object may be, for example, a magnetoresistive memory element (MRAM element) formed in the wafer WF. For the sake of simplicity of explanation, the wafer WF may be referred to as the test object. The test object is not limited to the MRAM element formed on the wafer WF, and may also be an MRAM element reassembled into a chip or the like.

The device (W1 to W3) for returning the wafer WF may include a wafer return robot W1, a pre-wafer alignment device W2, and a wafer supply cassette W3. The wafer return robot W1 may return the wafer WF to be measured, from the wafer supply cassette W3 into an internal space of the device 1. The pre-wafer alignment device W2 may correct a rotation angle or shift of the wafer WF. After adjustment by the pre-wafer alignment device W2, the wafer WF may be returned to the stage STG of the device 1.

The base (B1 to B4) of the device 1 may include a precision granite surface plate (base plate) B1, an active vibration isolation table (Isolator) B2, a wedge B3, and a dispersion plate B4. The precision granite surface plate B1 may be a foundation on which the member such as the stage STG, the optical system 30, or the like is disposed. The active vibration isolation table B2 may suppress vibration of members on the precision granite surface plate B1. The wedge B3 may perform horizontal adjustment of the precision granite surface plate B1 and the active vibration isolation table B2. The dispersion plate B4 may distribute device load to a floor.

The information processing unit 50 may process information detected by the detector 40. The information processing unit 50 may have a function of receiving an image acquired by a TDI camera, a CCD camera, or the like, and a signal acquired from the measuring unit MS such as a microwave generator 23 or the like, and of processing the image and the signal.

The power source/controller 60 may supply power to the device 1, and may control each unit of the device 1. For example, the controller 60 may control the magnetic field generating unit 10, the magnetic field generating unit 20, the actuator A10, and the actuator A20. The device 1 may also measure magnetic characteristics of the wafer WF under atmospheric conditions (e.g., such as a typical room temperature and a pressure of 1 atm when the wafer WF is exposed to typical atmospheric air). In addition, the device 1 may additionally have a temperature controller controlling the temperature of the wafer WF. Each of the power source/controller 60 and information processing unit 50 may include one or more of the following components: at least one central processing unit (CPU) configured to execute computer program instructions to perform various processes and methods, random access memory (RAM) and read only memory (ROM) configured to access and store data and information and computer program instructions, and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller or processor can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

The stage STG may mount the wafer WF as the test object. The stage STG may be referred to as a mount. The stage STG may include a stage surface ST1. The device 1 may measure magnetic characteristics of the MRAM element in the wafer WF mounted on the stage surface ST1 of the stage STG. The stage STG may have a wafer chuck for holding the wafer WF. The wafer WF may be fixed on the stage surface ST1 by the wafer chuck by vacuum or static electricity.

The actuator A20 may be mounted on the stage STG. The actuator A20 may move the stage STG. The actuator A20 may have an XYZθ driving shaft by, for example, a linear motor, a ball screw, a VCM, a piezo, or the like. A measurement surface Z0 may be introduced as a surface, parallel to the stage surface ST1. For example, the measurement surface Z0 may include an upper surface of the wafer WF. Then, the wafer WF (MRAM element) fixed to the stage surface ST1 may move on a surface, parallel to the measurement surface Z0. A position of the wafer WF and a position of the MRAM element may be measured by a laser interferometer 14. In this manner, the actuator A20 may move the MRAM element fixed to the stage STG on the surface, parallel to the stage surface ST1. For example, the actuator A20 may move the MRAM element in a straight line in one direction on the surface, parallel to the measurement surface Z0.

In this case, for the convenience of explaining the device 1, an XYZ orthogonal coordinate system may be introduced. A direction, orthogonal to the measurement surface Z0, may be defined as a Z-axis direction, and two orthogonal directions within a plane, parallel to the measurement surface Z0, may be defined as an X-axis direction and a Y-axis direction. A+Z-axis direction may be defined as an upward direction, and a −Z-axis direction may be defined as a downward direction. In addition, the upward and downward directions may be for convenience of explanation, and do not necessarily indicate a direction in which the device 1 is actually disposed.

As illustrated in FIG. 1, in the present embodiment, a configuration of an XYZθ stage is illustrated. However, a device may be arranged in a configuration by a rθ stage.

The magnetic field generating unit 10 may generate a different gradient magnetic field depending on a position. In a conventional gradient magnetic field, a magnetic field of a coil itself may fluctuate by changing a current value of the coil. In the present embodiment, the “different gradient magnetic field depending on a position” may mean, for example, a gradient magnetic field of which a static magnetic field intensity varies depending on a position. More specifically, the different gradient magnetic field depending on a position may result from a plurality of magnetic field generating sources having different magnetic field directions being disposed at different positions, and the test object may move within a magnetic field to fluctuate the magnetic field applied to the test object. The magnetic field generating unit 10 may be referred to as a first magnetic field generating unit 10.

The magnetic field generating unit 10 may be a magnetic field generator disposed in an upward direction from the stage STG (e.g., above the stage STG). The magnetic field generating unit 10 may include a plurality of magnet units. Each magnet unit of the plurality of magnet units may include an electromagnet (e.g., one of electromagnets 11 and 12). The plurality of magnet units are not limited to electromagnets 11 and 12, and may include simple magnets.

A plurality of electromagnets 11 and 12 may be disposed spaced apart from each other in the X-axis direction. The plurality of electromagnets 11 and 12 may include two electromagnets 11 and 12 of which applied currents are independently controlled, or may include two electromagnets 11 and 12 of which applied currents are non-independently controlled. An optical path of incident light transmitted through an objective lens 34 for MOKE measurement, and an optical path of reflected light in which the incident light is reflected from the wafer WF, may be disposed between two of the plurality of electromagnets 11 and 12. In this manner, an optical path between the objective lens 34 and the wafer WF may be disposed between two or more magnet units. The magnetic field generating unit 10 may be disposed inside the frame 13. The device 1 may additionally include an actuator A30 moving the magnetic field generating unit 10.

FIG. 5 is a graph illustrating a magnetic field component in a Z-axis direction of a magnetic force line on a measurement surface Z0 in a device 1 for measuring magnetic characteristics according to an embodiment, wherein a horizontal axis represents a position in an X-axis direction on the measurement surface Z0, and a vertical axis represents the magnetic field component in the Z-axis direction of the magnetic force line on the measurement surface Z0. FIG. 5 may illustrate results of calculating and measuring the magnetic field component in the Z-axis direction of the magnetic force line under various conditions.

As illustrated in FIG. 2 and FIG. 5, the plurality of electromagnets 11 and 12 may generate a gradient magnetic field on the measurement surface Z0. The plurality of electromagnets 11 and 12 may generate a gradient magnetic field in which a direction of the magnetic field component in the Z-axis direction, orthogonal to the measurement surface Z0, changes from the −Z-axis direction to the +Z-axis direction, depending on a position of the measurement surface Z0. In this case, the −Z-axis direction may be a direction, opposite to the +Z-axis direction. Specifically, the gradient magnetic field may have a portion in which a direction of the magnetic field changes from the −Z-axis direction to the +Z-axis direction, for example, as the position moves from the −X-axis direction to the +X-axis direction. A magnitude of the magnetic field may decrease from an end portion in the −X-axis direction toward a central portion, and may become 0 in the central portion. In addition, the magnitude of the magnetic field may increase from the central portion toward the end portion in the +X-axis direction. In this manner, the plurality of electromagnets 11 and 12 may generate a magnetic field that may be constant in time and may be different depending on a position. Therefore, the gradient magnetic field may also be a static magnetic field.

The magnetic field generating unit 20 may generate a high-frequency magnetic field that may be variable in time (i.e., is time-varying). For example, the magnetic field generating unit 20 may generate a microwave magnetic field of which a frequency changes with time. Specifically, the magnetic field generating unit 20 may generate an alternating current magnetic field (AC magnetic field) of 0 to 50 GHz. For example, the magnetic field generating unit 20 may generate a microwave magnetic field used for FMR measurement. The magnetic field generating unit 20 may be referred to as a second magnetic field generating unit 20. The magnetic field generating unit 20 may be disposed between the stage STG and the electromagnets 11 and 12. Specifically, the magnetic field generating unit 20 may be disposed between the wafer WF disposed on the stage STG and the electromagnets 11 and 12. The magnetic field generating unit 20 may also be fixed in a downward direction from the frame 13. The magnetic field generating unit 20 may generate, for example, an AC magnetic field in the Y-axis direction.

As illustrated in FIGS. 3 and 4, the magnetic field generating unit 20 may include, for example, a plurality of electric signal probes 21a and 21b, a base 22, a microwave generator 23, and a height sensor 24. The electric signal probe 21a or the like may be simply referred to as a probe. The plurality of electric signal probes 21a and 21b may be collectively referred to as an electric signal probe 21. The number of electric signal probes 21 is not limited to two, and may be one, or may be three or more. As described below, a plurality of electric signal probes 21 may be disposed in a zigzag manner.

The base 22 may support the electric signal probe 21. The base 22 may include, for example, a dielectric such as glass or the like, and may be a rectangular plate. Plate surfaces of the base 22 may face in upward and downward directions. A slit 25 (e.g., opening) may be formed in the base 22 that penetrates from an upper plate surface to a lower plate surface. The slit 25 may be formed in a rectangular shape on the plate surface, for example. The slit 25 may be used as an optical path of incident light transmitted through the objective lens 34 for MOKE measurement, and an optical path of reflected light in which the incident light is reflected from the wafer WF. In this manner, the magnetic field generating unit 20 may include the base 22 having a structure in which a center is hollow or open. The magnetic field generating unit 20 may include the slit 25 disposed such that an optical path between the objective lens 34 and the wafer WF is conductive. In addition, the slit 25 may have a function of avoiding interference between laser light for an optical autofocus sensor and the electric signal probe 21.

The electric signal probe 21 may be disposed in the +X-axis and −X-axis directions of the slit 25 on the lower plate surface of the base 22. For example, the electric signal probe 21a may be disposed in the −X-axis direction of the slit 25 on the lower plate surface of the base 22, and the electric signal probe 21b may be disposed in the +X-axis direction of the slit 25 on the lower plate surface of the base 22.

The microwave generator 23 may be a vector network analyzer, for example, generating an AC magnetic field of 0 GHz to 50 GHz. A terminal connected to the microwave generator 23 may be connected to a terminal in a +Y-axis direction and a terminal in a −Y-axis direction of the electric signal probe 21a by a signal line. Therefore, the electric signal probe 21a may be disposed to face the Y-axis direction (e.g., to extend in the Y-axis direction). The electric signal probe 21b may also be disposed to face the Y-axis direction (e.g., to extend in the Y-axis direction). In this manner, the electric signal probe 21 may be disposed to face the Y-axis direction, orthogonal to the X-axis direction, which may be a scanning direction of the wafer WF. When a high-frequency electric field is generated in the signal line, a magnetic field may be generated. In FIG. 3, an example of generating an AC magnetic field by a cobra-shaped line is illustrated, but may also be a coaxial line, a strip line, or a microstrip line.

The height sensor 24 may sense a height from the measurement surface Z0 of the magnetic field generating unit 20. The height sensor 24 may be, for example, a capacitance type.

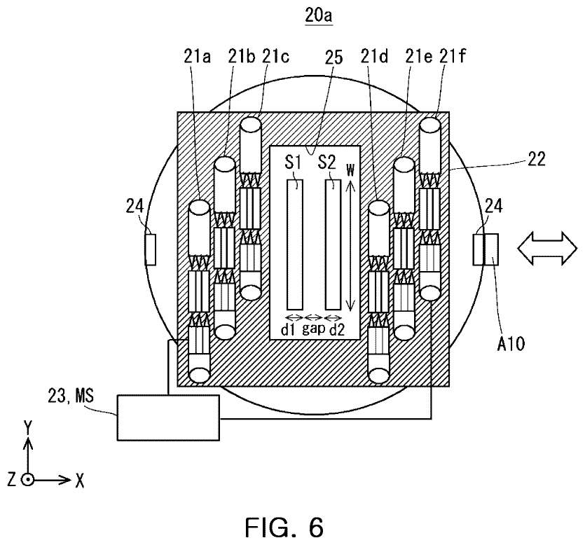

FIG. 6 is a view illustrating a magnetic field generating unit 20a in a device for measuring magnetic characteristics according to an embodiment. As illustrated in FIG. 6, three or more electric signal probes 21a to 21f disposed to face or extend in the Y-axis direction may be disposed side by side in the X-axis direction or may be disposed in a zigzag shape. An actuator A10 may move a magnetic field generating unit 20a. The actuator A10 may be mounted on, for example, a base 22. The actuator A10 may move, for example, the magnetic field generating unit 20a in the X-axis direction. The actuator A10 may be referred to as a first actuator. In this regard, an actuator A20 of a stage STG, as described above, may be referred to as a second actuator.

A measuring unit MS may measure magnetic characteristics of a MRAM disposed on a wafer WF moving in a gradient magnetic field. The measuring unit MS may be disposed near the wafer WF. The measuring unit MS may be a vector network analyzer of a microwave generator 23.

As illustrated in FIG. 1, the device 1 may include the optical system 30. Depending on an embodiment, the device 1 may not include the optical system 30. The device 1 may include the optical system 30, when measuring magnetic characteristics using an MOKE. Therefore, the device 1 may measure the magnetic characteristics, and may measure a polarization state of the reflected light reflected from the wafer WF. The device 1 may not include the optical system 30, when measuring magnetic characteristics using an FMR.

The optical system 30 may include an optical microscope. The optical microscope may observe a surface of the wafer WF. The optical system 30 may include a light source 31, a filter 32, a polarizer 33, an objective lens 34, an analyzer 35, a filter 36, an AF sensor 37 for obtaining a focus of the wafer WF, and several lenses P1 to P9 and several mirrors M1 to M4.

The light source 31 may generate illumination light. The illumination light may be, for example, laser light. The illumination light generated and radiated from the light source 31 may transmit through the filter 32. Therefore, the illumination light may include a predetermined wavelength band. The illumination light passing through the filter 32 may be incident on the polarizer 33. The polarizer 33 may convert the generated illumination light into linearly polarized light. The illumination light including the linearly polarized light may be reflected by a mirror M2, and may be focused on the wafer WF by the objective lens 34. The mirror M2 may be, for example, a non-polarized beam splitter separating the illumination light.

The objective lens 34 may be for forming an image of a pattern on the wafer WF, and may generally be selected to be non-magnetic. The objective lens 34 may form an image of the illumination light on the wafer WF. When the wafer WF includes a magnetoresistive memory element, a polarization angle of the linearly polarized light may change due to a magneto-optical Kerr effect. Reflected light reflected from the wafer WF may be transmitted through the objective lens 34, and may be incident on the analyzer 35. The analyzer 35 may detect a change in the polarization angle of the linearly polarized light included in the reflected light. For example, the analyzer 35 may detect a rotational component in the linearly polarized light of the reflected light. The analyzer 35 may include, for example, a photodetector. The reflected light transmitted through the analyzer 35 may be incident on the detector 40 via the filter 36. The AF sensor 37 may be a member for connecting focus of a surface of the wafer WF. The AF sensor 37 may use a semiconductor laser light source having a wavelength, longer or shorter than a wavelength of the illumination light and the reflected light used in the optical system 30.

The detector 40 may acquire a pattern of the wafer WF. The detector 40 may have a plurality of line sensors L1 and L2 and a review monitor 42. The plurality of line sensors L1 and L2 may be collectively referred to as a line sensor 41. The number of line sensors 41 is not limited to two, and may be three or more. The plurality of line sensors 41 may include, for example, a time delay integration (TDI) sensor. The line sensor 41 may acquire a scanned image by scanning illumination light on the wafer WF. The review monitor 42 may include a charge-coupled device (CCD) sensor. The CCD sensor may be used for review. A mirror M3 may be inserted to convert an optical path between the line sensor (L1 and L2) and the review monitor 42.

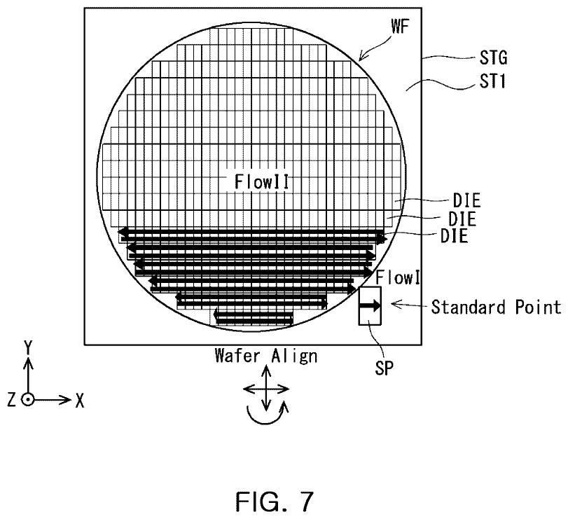

FIG. 7 is a plan view illustrating a stage surface ST1 of a stage STG and a wafer WF in a device 1 for measuring magnetic characteristics according to an embodiment. As illustrated in FIG. 7, a wafer WF may be mounted on a stage surface ST1. On the stage surface ST1, the wafer WF may be aligned by movement in the X-axis direction and the Y-axis direction and rotation around a Z-axis. In addition, a standard position SP may be provided on the stage surface ST1. The standard position SP may be a predetermined position or a standard point. A sample for preliminary measurement may be installed on the standard position SP. The sample for preliminary measurement may be, for example, a chip for calibration. The wafer WF, in the standard position, may be at a particular location with respect to the sample for preliminary measurement (e.g., with respect to a chip for calibration in a pre-set position).

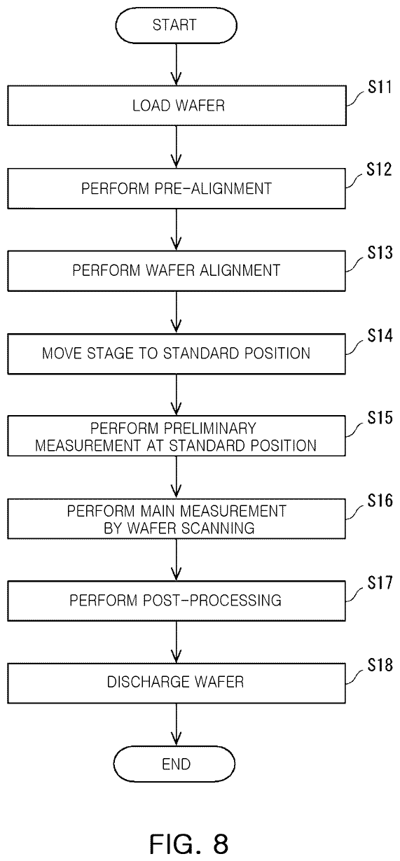

Next, a method for measuring magnetic characteristics performed using the device 1 of the present embodiment will be described. FIG. 8 is a flow chart illustrating a method for measuring magnetic characteristics using a device 1 for measuring magnetic characteristics according to an embodiment. As illustrated in FIG. 8, a method for measuring magnetic characteristics of the present embodiment may include standard position measurement Flow I as preliminary measurement, and wafer scan Flow II as main measurement. In this manner, the preliminary measurement and the main measurement may be performed in the present embodiment. The preliminary measurement may be referred to as a first measurement mode, and the main measurement may be referred to as a second measurement mode.

In the preliminary measurement, a relationship between a frequency and characteristics of a magnetic field may be measured in advance for a sample for preliminary measurement disposed at a standard position SP.

In the main measurement, based on the relationship obtained from the preliminary measurement, a predetermined range of frequencies may be selected, and then magnetic characteristics of a test object in the predetermined range of frequencies may be measured. For example, while a position of a magnetic field generating unit 20 is fixed, magnetic characteristics of a wafer WF may be measured by a measuring unit MS while moving a stage STG by an actuator A20. Specifically, a controller 60 may execute the first measurement mode for specifying a resonance frequency of the wafer WF, based on the magnetic characteristics of the wafer WF measured in the preliminary measurement. Then, the controller 60 may measure the magnetic characteristics of the wafer WF in the frequency range including the resonance frequency in the main measurement.

As illustrated in S11 of FIG. 8, first, a wafer WF may be mounted on a device 1 for measuring magnetic characteristics. Specifically, a wafer return robot W1 may return the wafer WF to be inspected, from a wafer supply cassette W3 to an internal space of the device 1. Next, as illustrated in S12, a pre-wafer alignment device W2 may correct a rotation angle or shift of the wafer WF. After adjusting the wafer WF in the pre-wafer alignment device W2, the wafer WF may be returned to a stage STG of the device 1.

Next, as illustrated in S13, alignment of the wafer WF may be performed on the stage STG. For example, alignment of the wafer WF may be performed using a laser interferometer 14 and an actuator A20. Next, as illustrated in S14, the stage STG may move to a standard position SP. Specifically, to measure a sample on the standard position SP, the stage STG may move such that an optical path falls on the sample. Next, as illustrated in S15, preliminary measurement on the standard position SP may be performed.

Next, as illustrated in S16, main measurement by wafer scanning may be performed. Next, as illustrated in S17, post-measurement processing may be performed. Then, as illustrated in S18, the wafer WF may be removed from the stage STG.

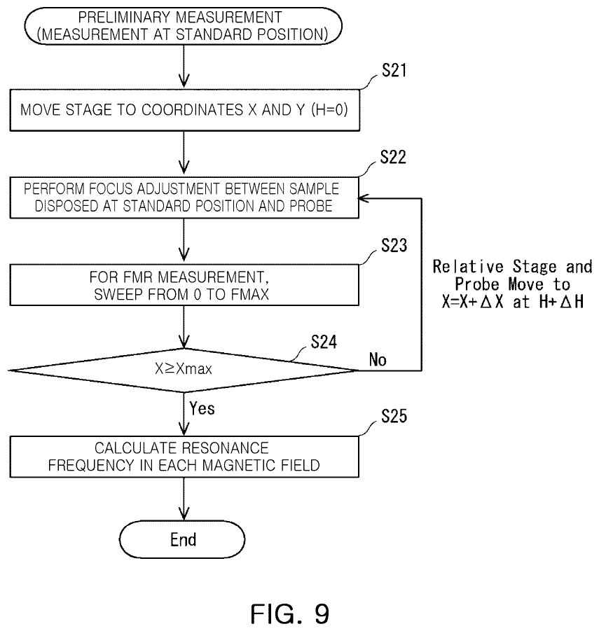

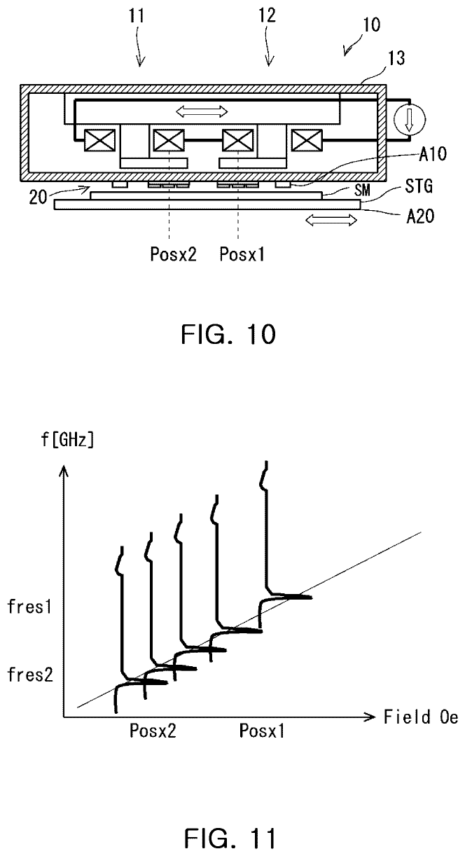

FIG. 9 is a flow chart illustrating preliminary measurement in a method for measuring magnetic characteristics using a device 1 for measuring magnetic characteristics according to an embodiment. FIG. 10 is a cross-sectional view illustrating a positional relationship between a wafer WF, a magnetic field generating unit 10, and a magnetic field generating unit 20 in preliminary measurement in a method for measuring magnetic characteristics using a device 1 for measuring magnetic characteristics according to an embodiment. FIG. 11 is a graph illustrating magnetic characteristics acquired by a measuring unit MS in preliminary measurement in a method for measuring magnetic characteristics using a device 1 for measuring magnetic characteristics according to an embodiment, wherein a horizontal axis represents a position corresponding to a gradient magnetic field, and a vertical axis represents a frequency.

As illustrated in S21 of FIG. 9, a stage STG may move to a predetermined position below a magnetic field generating unit 10 generating a gradient magnetic field. Specifically, the stage STG may move to coordinates X and Y by an actuator A20 (H=0). By the movement, position alignment between a sample disposed at a standard position SP and a magnetic field generating unit 20 may be performed.

Next, as illustrated in S22, focus adjustment may be performed between the sample disposed at the standard position SP and the magnetic field generating unit 20 including an electric signal probe 21. For example, as illustrated in FIG. 10, a sample SM and a magnetic field generating unit 20 may move relative to a magnetic field generating unit 10. Specifically, a controller 60 may move the magnetic field generating unit 20 together with the sample SM relative to the magnetic field generating unit 10 in a first measurement mode. Therefore, a minimum value Hlow to a maximum value Hup of a gradient magnetic field may be applied to the sample SM. In this manner, H refers to a magnetic field strength, such that in one embodiment, H=0 is 0 magnitude, Hlow is a lowest non-zero magnitude that exists when the magnetic field generating unit 20 together with the sample SM move relative to the magnetic field generating unit 10, and Hup is a highest magnitude that exists when the magnetic field generating unit 20 together with the sample SM move relative to the magnetic field generating unit 10.

Next, as illustrated in S23, a frequency in FMR measurement may be swept. For example, a frequency may be swept from 0 to a maximum value fmax. Therefore, magnetic characteristics illustrated in FIG. 11 may be obtained.

Next, as illustrated in S24, it is determined whether a position in the X-axis direction of the magnetic field generating unit 20 together with the sample SM relative to the magnetic field generating unit 10 is at a pre-set maximum amount (e.g., has moved a particular amount from a reference position). When the position in the X-axis direction of the magnetic field generating unit 20 together with the sample SM relative to the magnetic field generating unit 10 does not exceed the maximum position (if No), S22 and S23 may be continued. For example, the stage STG may move by the actuator A20. Therefore, the minimum value Hlow to the maximum value Hup of the gradient magnetic field may again be applied to the sample SM disposed at the standard position SP.

In S24, when the position in the X-axis direction of the magnetic field generating unit 20 together with the sample SM relative to the magnetic field generating unit 10 exceeds the maximum position (if Yes), a resonance frequency fres in each magnetic field may be calculated, as illustrated in S25. For example, the resonance frequency fres may be obtained from a graph of FIG. 11. In this manner, a relationship between a frequency and characteristics of the magnetic field in the sample SM disposed at the standard position SP may be measured in advance. It is assumed that the resonance frequency fres has a linear relationship with respect to the magnetic field.

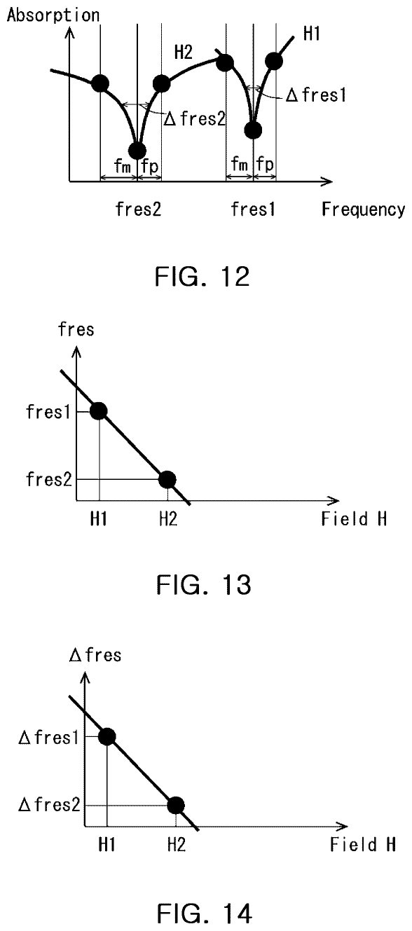

FIG. 12 is a graph illustrating a resonance frequency in each magnetic field in a device 1 for measuring magnetic characteristics according to an embodiment, wherein a horizontal axis represents a frequency and a vertical axis represents an absorption amount (e.g., light absorption amount, which may be a relative light absorption amount at a surface of a die or wafer). As can be seen, for frequencies around each resonant frequency, the absorption amount may be a minimum at the resonance frequency, and may increase in both directions away from the resonant frequency. As illustrated in FIG. 12, frequencies before and after a resonance frequency fres, e.g., a frequency (fres−fm) and a frequency (fres+fp), may be selected. A frequency fm and a frequency fp may be selected according to specifications of a device 1 for measuring magnetic characteristics. In addition, a predetermined amount of width of a peak of the resonance frequency fres may be referred to as a resonance frequency width Δfres. For example, the resonance frequency width Δfres may be a half-width of the peak of the resonance frequency fres, or the like.

FIG. 13 is a graph illustrating a relationship between a resonance frequency fres and a magnetic field in a device 1 for measuring magnetic characteristics according to an embodiment, wherein a horizontal axis represents the magnetic field and a vertical axis represents a resonance frequency fres. In a magnetic field H1, a resonance frequency fres1 may be represented, and in a magnetic field H2, a resonance frequency fres2 may be represented. As illustrated in FIG. 13, a resonance frequency fres may have a linear relationship with respect to a magnetic field H.

FIG. 14 is a graph illustrating a relationship between a resonance frequency width Δfres and a magnetic field in a device 1 for measuring magnetic characteristics according to an embodiment, wherein a horizontal axis represents the magnetic field and a vertical axis represents a resonance frequency width Δfres. In a magnetic field H1, a resonance frequency width Δfres1 may be represented, and in a magnetic field H2, a resonance frequency width Δfres2 may be represented. As illustrated in FIG. 14, a resonance frequency width Δfres may have a linear relationship with respect to a magnetic field H.

From FIG. 13 and FIG. 14, for example, as described in Non-Patent Document 1, by using the Landau-Lifshitz-Gilbert Equation (LLG equation), an anisotropic magnetic field (Hk) and a damping coefficient (a) may be obtained. Non-Patent Document 1 will be described later.

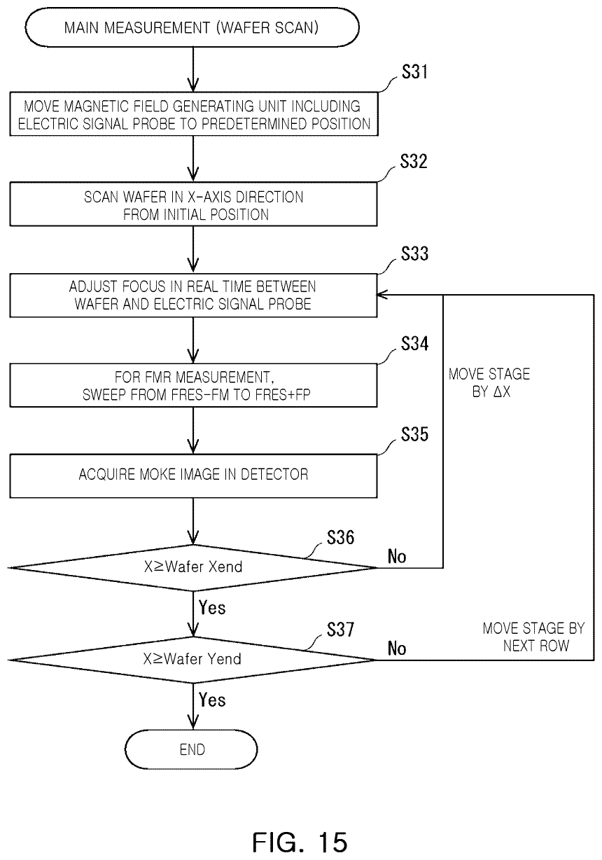

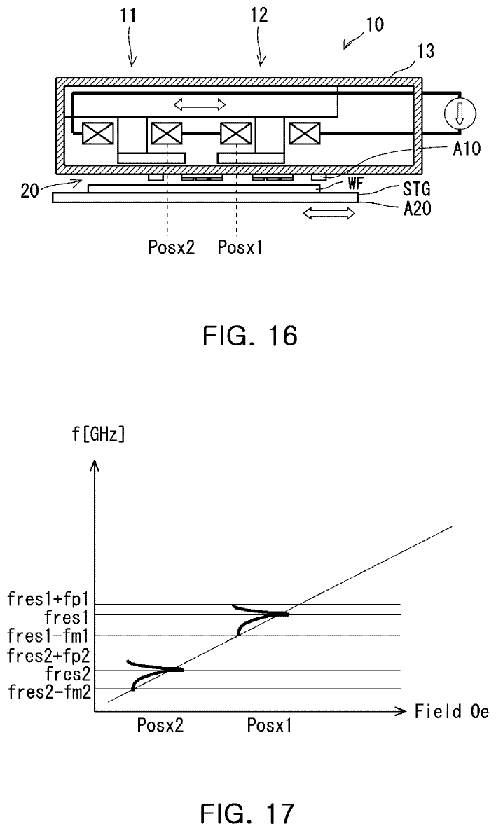

FIG. 15 is a flow chart illustrating main measurement in a method for measuring magnetic characteristics using a device 1 for measuring magnetic characteristics according to an embodiment. FIG. 16 is a cross-sectional view illustrating a positional relationship between a wafer WF, a magnetic field generating unit 10, and a magnetic field generating unit 20 in main measurement in a method for measuring magnetic characteristics using a device 1 for measuring magnetic characteristics according to an embodiment. FIG. 17 is a graph illustrating magnetic characteristics acquired by a measuring unit MS in main measurement in a method for measuring magnetic characteristics using a device 1 for measuring magnetic characteristics according to an embodiment, wherein a horizontal axis represents a position corresponding to a gradient magnetic field, and a vertical axis represents a frequency.

As illustrated in S31 of FIG. 15, a magnetic field generating unit 20 including an electric signal probe 21 may move to a predetermined position below a magnetic field generating unit 10 generating a gradient magnetic field.

Next, as illustrated in S32, a wafer WF may be scanned in the X-axis direction from an initial position. For example, as illustrated in FIG. 16, a wafer WF may move relative to a magnetic field generating unit 10 and a magnetic field generating unit 20. A controller 60 may move the wafer WF relative to the magnetic field generating unit 10 and the magnetic field generating unit 20 in a second measurement mode.

Next, as illustrated in S33, focus may be adjusted in real time between the wafer WF and the electric signal probe 21.

Next, as illustrated in S34, a frequency in FMR measurement may be swept. For example, in this measurement, a frequency may be swept from (fres2−fm2) to (fres2+fp2) and from (fres1−fm1) to (fres1+fp1). Therefore, magnetic characteristics illustrated in FIG. 17 may be acquired.

Next, as illustrated in S35, an optical system 30 may be used to obtain an image by MOKE. A detector 40 such as TDI or the like may acquire an image by MOKE.

Next, as illustrated in S36, it may be determined whether a position in the X-axis direction is an end portion on the +X-axis direction or the −X-axis direction in the X-axis direction of the wafer WF. For example, a certain X-axis position of the magnetic field generating unit 20 including the electric signal probe 21 will correspond to an end portion in the X-axis direction of the wafer WF. When the X-axis position in the X-axis direction does not exceed the end portion (if No), a position of a stage STG may move by AX, and S33 to S35 may be continued.

In S36, when the X-axis position in the X-axis direction exceeds the end portion of the wafer WF in the X-axis direction (if Yes), it may be determined whether a Y-axis position in the Y-axis direction is an end portion on the +Y-axis direction in the Y-axis direction of the wafer WF, as illustrated in S37. When the position in the Y-axis direction does not exceed the end portion (if No), the position of the stage STG may move by the next row, and S33 to S36 may be continued.

In S37, when the Y-axis position in the Y-axis direction exceeds the end portion of the Y-axis direction of the wafer WF (if Yes), processing may be terminated.

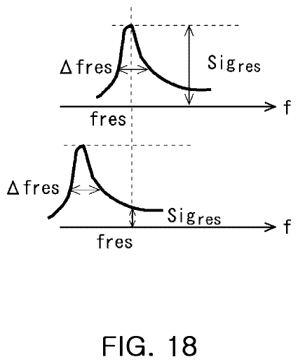

FIG. 18 is a graph illustrating a resonance frequency fres in each magnetic field in a device 1 for measuring magnetic characteristics according to an embodiment, wherein a horizontal axis represents a frequency and a vertical axis represents an absorption amount. As illustrated in FIG. 18, a resonance frequency width Δfres may be obtained from a signal Sigres having a resonance frequency fres obtained by main measurement as a peak. Therefore, in main measurement, an anisotropic magnetic field (Hk) and a damping coefficient (a) of each MRAM element may be obtained by entirely scanning a wafer WF. Specifically, as described in, for example, Non-Patent Document 1, the anisotropic magnetic field (Hk) may be obtained from an FMR measurement signal of FIG. 18. In this case, in equation 1 of Non-Patent Document 1, an anisotropic field (Hkeff) may be expressed as the anisotropic magnetic field (Hk), and in equation 2, α (damping constant) may be expressed as the damping coefficient (α). In equation 1 of Non-Patent Document 1, Lande's g factor, magnetic permeability in vacuum (μ0), Bohr magnetization (μb), a Planck constant (h), and an out-of-plane magnetic field (μ0Hout) may be represented, and graphs of FIGS. 1(b) and (c) of Non-Patent Document 1 may be examples of derivation of the anisotropic magnetic field (Hk) and the damping coefficient (α).

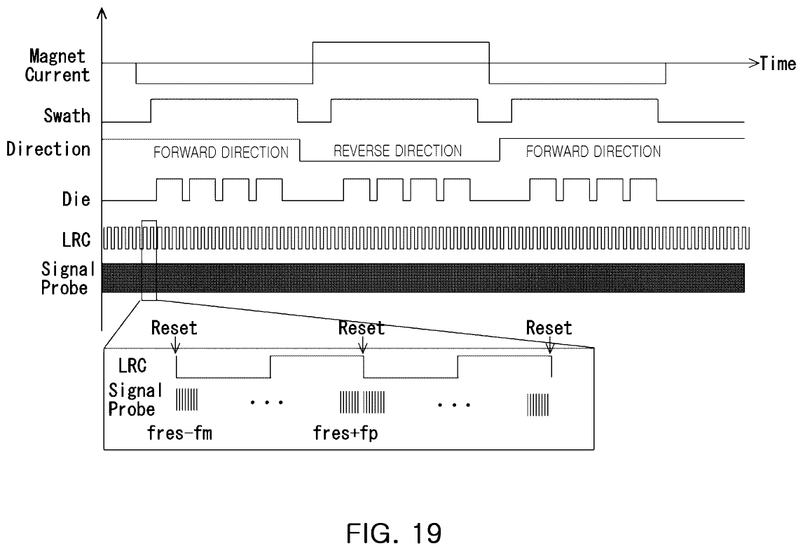

FIG. 19 is a sequence diagram illustrating a method for measuring magnetic characteristics of a die DIE included in a wafer WF according to an embodiment, wherein a horizontal axis represents time, and a vertical axis represents a current of an electromagnet, an inspection table (Swath), a movement direction (Direction) of the wafer WF, an inspection period (Die) of the die DIE, an image capture clock (LRC) of a TDI, and a sweep pulse (Signal Probe) from a frequency (fres−fm) to a frequency (fres+fp), in sequence from the top.

A wafer WF may include an MRAM element having rectangular spatially repeating periodicity, called a die DIE. Inside the MRAM element, a memory region having repeating periodicity may be formed in an array shape. Movement during measurement by a line sensor 41 may acquire an image in a forward direction while moving in the X-axis direction to cross a plurality of dies DIE, as illustrated in FIG. 7. Once the image acquisition is completed, the image may move to the next measurement position in the Y-axis direction, and inspection may be performed in a reverse direction of the X-axis. As illustrated in FIG. 7, in inspecting all of the dies of the wafer WF, a movement direction of the line sensor 41 may be alternately repeated in forward and reverse directions. In addition, a pixel for filter processing or scan correction may be included to acquire an image without a gap.

For example, when the image capture clock (LRC) of the TDI is 400 kHz and the sweep pulse is 10 GHz, the number of sweep pulses becomes (1010)/(400×103)=25000 pulses/LRC. In the example of FIG. 19, the number of sweep pulses is illustrated to fit into 1 clock of the LRC, but a repetition cycle of the sweep pulse may also be adjusted to fit into 2 or more clocks of the LRC.

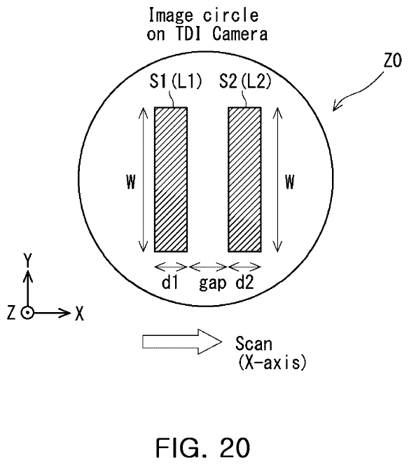

FIG. 20 is an image diagram illustrating a region (S1 and S2) on a measurement surface Z0 detected by a plurality of line sensors L1 and L2 in a device 1 for measuring magnetic characteristics according to an embodiment. As illustrated in FIG. 20, a plurality of line sensors L1 and L2 may detect a region (S1 and S2) extending in the Y-axis direction, respectively. The regions S1 and S2 may have lengths d1 and d2 in the X-axis direction and a length W in the Y-axis direction. The regions S1 and S2 may be disposed side by side with a gap in the X-axis direction.

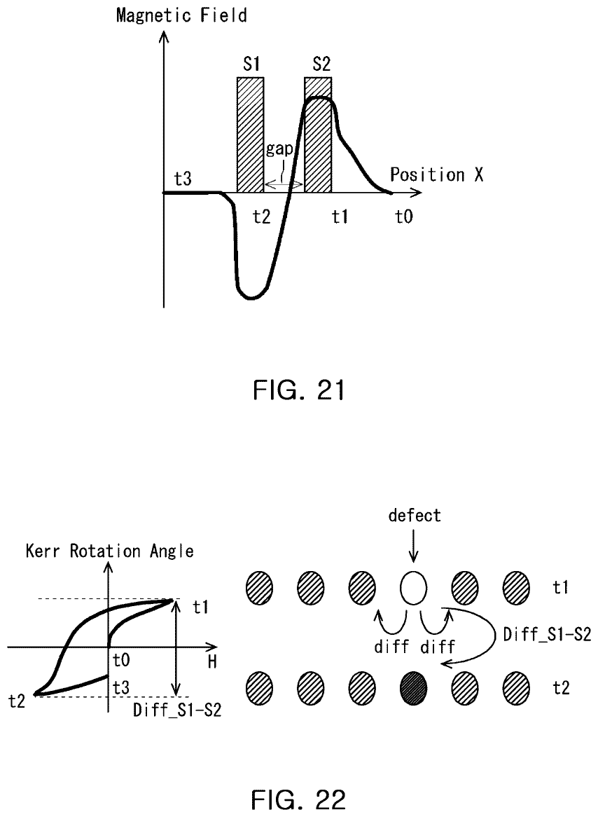

FIG. 21 is a graph illustrating a magnetic field component in a Z-axis direction on a measurement surface Z0 in a device 1 for measuring magnetic characteristics according to an embodiment, wherein a horizontal axis represents a position in an X-axis direction on the measurement surface Z0, and a vertical axis represents the magnetic field component in the Z-axis direction on the measurement surface Z0. FIG. 21 also illustrates a region (S1 and S2) on a measurement surface Z0 measured by each line sensor. FIG. 22 is a graph illustrating a Kerr rotation angle on a measurement surface Z0 in a device 1 for measuring magnetic characteristics according to an embodiment, wherein a horizontal axis represents a magnetic field component in a Z-axis direction of an external magnetic field, and a vertical axis represents the Kerr rotation angle. FIG. 22 also schematically illustrate a luminance diagram of a plurality of MRAM elements.

As illustrated in FIGS. 21 and 22, at time t=t0, an MRAM element may be located in a region in which a magnetic field component in the Z-axis direction is 0. When the MRAM element moves in the X-axis direction, an external magnetic field received by the MRAM element may increase. Therefore, a Kerr rotation angle may also increase. The Kerr rotation angle may be saturated when the Kerr rotation angle reaches a certain value, and may not be changed even when the external magnetic field increases (time t=t1). A line sensor L2 may obtain luminance by a Kerr rotation angle of a plurality of magnetoresistive memory elements (MRAM) aligned in the Y-axis direction at time t=t1.

Further, when the MRAM element moves in the X-axis direction, the external magnetic field received by the MRAM element may be reduced. Therefore, the Kerr rotation angle may also be reduced. Furthermore, the external magnetic field may be 0. Furthermore, when the MRAM element moves in the X-axis direction, the external magnetic field received by the MRAM element may be reversed. Therefore, the Kerr rotation angle may be reduced. When the MRAM element moves in the X-axis direction, the external magnetic field received by the MRAM element in a reverse direction may increase. Therefore, the Kerr rotation angle may be further reduced.

When the external magnetic field in a reverse direction increases at time t-t2, the Kerr rotation angle may be reduced and the luminance may also be reduced. A line sensor L1 may acquire luminance by a Kerr rotation angle of a plurality of MRAM elements aligned in the Y-axis direction at time t-t2. Furthermore, when the MRAM element moves in the X-axis direction, the external magnetic field in a reverse direction received by the MRAM element may be reduced. The external magnetic field may become 0.

As illustrated in FIG. 22, in the present embodiment, the line sensor L2 may obtain the luminance of the plurality of MRAM elements at time t=t1. In addition, the line sensor L1 may obtain the luminance of the plurality of MRAM elements at time t=t2. In this manner, in the present embodiment, the line sensor L2 may detect a magneto-optical effect of the MRAM element at a position at time t=t1 by moving a position of the MRAM element in a gradient magnetic field. The line sensor L1 may detect a magneto-optical effect of the MRAM element at a position at time t=t2. Therefore, the plurality of line sensors L2 and L1 may detect a magneto-optical effect by a magnetic field component in the +Z-axis direction, and a magneto-optical effect by a magnetic field component in the −Z-axis direction, respectively.

At time t=t1, when a defect exists in a plurality of MRAM elements aligned in the Y-axis direction, the line sensor L2 may detect luminance of the defect. A defective MRAM element may exhibit luminance, different from luminance of a neighboring normal MRAM element. In addition, at time t=t2, when a defect exists in a plurality of MRAM elements aligned in the Y-axis direction, the line sensor L1 may detect luminance of the defect. A defective MRAM element may exhibit luminance, different from luminance of a neighboring normal MRAM element.

An information processing unit 50 may process magneto-optical effects detected by the plurality of line sensors L1 and L2. Specifically, the information processing unit 50 may inspect the MRAM element from a difference between a magneto-optical effect detected by the line sensor L1 and a magneto-optical effect detected by the line sensor L2. For example, the information processing unit 50 may detect a difference Diff between luminance of an MRAM element that may be defective at time t=t1 detected by the line sensor L2, and luminance of an MRAM element that may be defective at time t=t2 detected by the line sensor L1. In this manner, the information processing unit 50 may compare the luminance of the same MRAM element at different times t1 and t2.

The information processing unit 50 may detect a difference diff between luminance of a defect detected by the line sensor L1 and luminance of a neighboring normal MRAM element, and may also detect a difference diff between luminance of a defect detected by the line sensor L2 and luminance of a neighboring normal MRAM element. In addition, the information processing unit 50 is not limited to two line sensors L1 and L2, and may process the magnetoresistance effect detected by three or more line sensors.

Next, an effect of the present embodiment will be described. A device 1 for measuring magnetic characteristics of the present embodiment may include a magnetic field generating unit 10 and a magnetic field generating unit 20, and may measure the resonance frequency for obtaining an anisotropic magnetic field (Hk) and a damping coefficient (α) by FMR. In addition, the device 1 may reduce a resonance frequency and magnetic field characteristics, measured in a main measurement, in a preliminary measurement in advance. Therefore, a measurement time period may be shortened.

In addition, the device 1 may simultaneously measure the anisotropic magnetic field (Hk) and the damping coefficient (α) by FMR, and may also measure an image by MOKE at high speed. Therefore, a defect of the wafer WF may be detected in a high degree of precision.

A device 1 for measuring magnetic characteristics of the present embodiment may have a gradient magnetic field. The gradient magnetic field may change a magnetic field component from the +Z-axis direction to the −Z-axis direction, depending on a position of a measurement surface Z0. The gradient magnetic field may be constant in time, and may vary depending on a position. A magnetic field applied to an MRAM element may be changed by moving the MRAM element within this gradient magnetic field. Therefore, distribution of a magnetic field generated by an electromagnet may be constant as the gradient magnetic field. Therefore, it is not necessary to change a current flowing to a coil of the electromagnet during inspection. Therefore, since a measurement speed due to responsiveness of the electromagnet is not reduced, a measurement time period may be shortened, and throughput may be improved.

In addition, magnetization distribution of the MRAM element may be monitored as an image, and may be integrated using measurement results of a line sensor 41 such as a TDI camera or the like. Therefore, high-sensitivity measurement is possible, and long-term imaging that has been performed so far may be unnecessary. In this manner, two or more line sensors 41, and a magnetic field generating unit 10 generating the gradient magnetic field for the MRAM element, may be used to shorten a measurement time period and improve defect detection capability.

Furthermore, the device 1 may independently convert a direction of a current in a plurality of electromagnets, to change a shape of magnetic field distribution to have vertical magnetic field distribution, and to measure hysteresis distribution.

### Embodiment 2

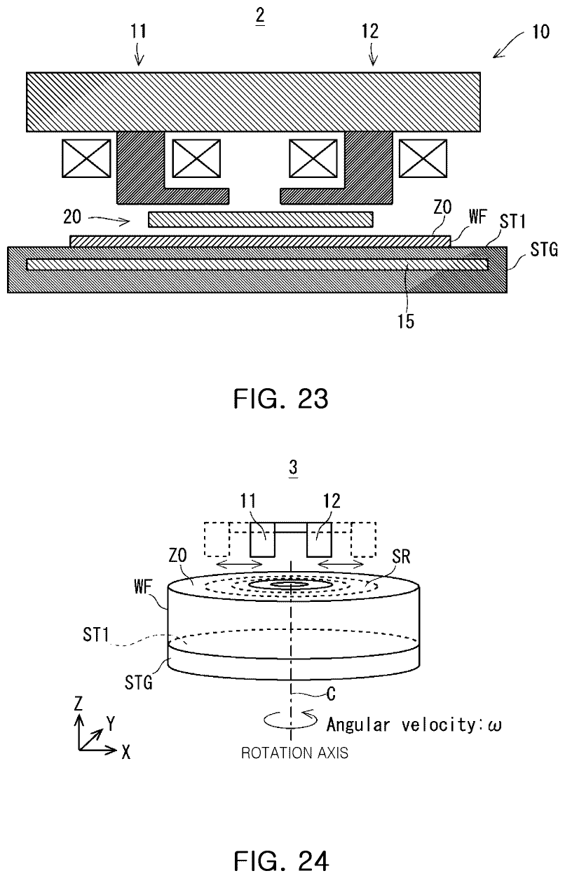

Next, a device for measuring magnetic characteristics according to an embodiment will be described. In a device for measuring magnetic characteristics of the present embodiment, a plate member including a magnetic body may be embedded in a stage STG. FIG. 23 is a cross-sectional view illustrating a stage STG and a magnetic field generating unit 10 in a device 2 for measuring magnetic characteristics according to an embodiment. As illustrated in FIG. 23, a stage STG in a device 2 for measuring magnetic characteristics may include a plate member 15. The plate member 15 may include or be formed of a magnetic material. The plate member 15 may be, for example, an iron plate. The plate member 15 is not limited to the iron plate when the iron plate includes the magnetic material. The plate member 15 may be embedded in an internal space of the stage STG, and may not be exposed to a stage surface ST1.

When viewed in a direction orthogonal to the stage surface ST1, a region surrounded by an external edge of the plate member 15 may include a magnetoresistive memory element (MRAM) fixed to the stage surface ST1. For example, when viewed in a direction orthogonal to the stage surface ST1, an area of the region surrounded by the external edge of the plate member 15 may be larger than an area of a wafer WF including the MRAM element fixed to the stage surface ST1.

When the wafer WF includes a plurality of MRAM elements and the wafer WF is fixed to the stage surface ST1, when viewed in a direction orthogonal to the stage surface ST1, the region surrounded by the external edge of the plate member 15 may include the wafer WF fixed to the stage surface ST1. For example, when viewed in a direction orthogonal to the stage surface ST1, an area of the region surrounded by the external edge of the plate member 15 may be larger than an area of the wafer WF fixed to the stage surface ST1. By having such a configuration, a gradient magnetic field may be stabilized. Configurations and effects, different from those described above, in embodiment 2, may be included in the description of embodiment 1.

### Embodiment 3

Next, a device for measuring magnetic characteristics according to an embodiment will be described. In the present embodiment, a stage STG may rotate about a rotation axis, orthogonal to a stage surface ST1. Therefore, the stage STG may rotate an MRAM element around a rotation axis, orthogonal to a measurement surface Z0. FIG. 24 is a perspective view illustrating a stage STG and a magnetic field generating unit 10 in a device 3 for measuring magnetic characteristics according to an embodiment. As illustrated in FIG. 24, a stage STG in a device 3 for measuring magnetic characteristics may have, for example, a disk shape. The stage STG may have a stage surface ST1, and may rotate around a rotation axis C, orthogonal to the stage surface ST1. A direction opposite to a clock-wise rotation direction around the rotation axis C may be defined as a +θ direction. In FIG. 24, a magnetic field generating unit 20 or the like will be omitted not to make the drawing complicated.

Two electromagnets 11 and 12, may be disposed above the stage surface ST1. A center position between an electromagnet 11 and an electromagnet 12 may be fixed. A distance between the electromagnet 11 and the electromagnet 12 may be changed. For example, when the center position between the electromagnet 11 and the electromagnet 12 is fixed on the rotation axis C, the electromagnet 11 and the electromagnet 12 may move in a radial direction of the stage STG. Therefore, the two electromagnets 11 and 12 may generate a gradient magnetic field by adjusting a mutual gap based on the position of the MRAM element to be measured. The center position between the electromagnet 11 and the electromagnet 12 is not limited to the rotation axis C.

When a center of a wafer WF is disposed on the rotation axis C, a plurality of line sensors 41 may measure magnetic field characteristics by the electromagnet 11 and the electromagnet 12, respectively. Each of the line sensors 41 may measure the magnetic field characteristics due to a magnetic field in the +Z-axis direction (+H) and a magnetic field in the −Z-axis direction (—H), as the wafer WF rotates once. A measurement region SR may have an annular shape centered on the rotation axis C on an inspection surface W0.

A distance from the center of the wafer WF to the electromagnet 11 (or electromagnet 12) may be defined as r. A tangential velocity v (linear speed) of the measurement region SR may depend on the distance r from the center of the wafer WF. For example, when v=rω, an angular velocity @ may be adjusted to match a scan speed of a line sensor 41 such as TDI or the like. Therefore, the line sensor 41 may acquire an image of a magneto-optical effect. According to the present embodiment, a rotating stage STG may be applied to have advantages such as saving return time, as compared to an XY stage, not needing to control an accumulation direction of the line sensor 41 such as TDI or the like with respect to a scan direction, or the like. Hereinafter, several modified examples of embodiment 3 may be illustrated.

### Modified Example 1

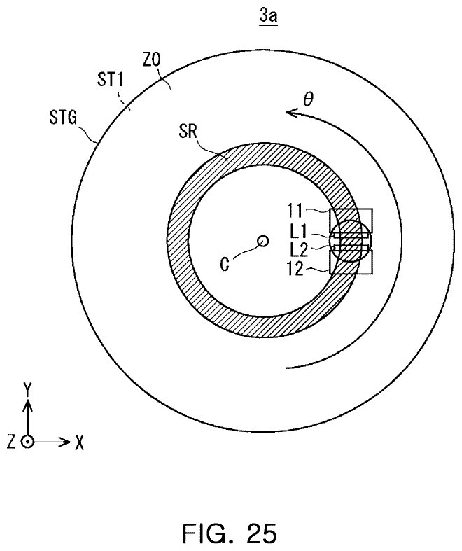

FIG. 25 is a plan view illustrating arrangement of a stage STG, electromagnets 11 and 12, and line sensors L1 and L2 in a device 3a for measuring magnetic characteristics according to modified example 1 of embodiment 3. As illustrated in FIG. 25, in a device 3a for measuring magnetic characteristics of this modified example, a center position between an electromagnet 11 and an electromagnet 12 on a stage surface ST1 may be located between a rotation axis C and a peripheral portion in the +X-axis direction of the stage surface ST1. The electromagnet 11 may be disposed in the +Y-axis direction of the center position, and the electromagnet 12 may be disposed in the −Y-axis direction of the center position. A gradient magnetic field may be formed in the Y-axis direction.

A plurality of line sensors L1 and L2 may be disposed between the electromagnet 11 and the electromagnet 12. The plurality of line sensors L1 and L2 may be extended in the X-axis direction. As a stage STG rotates, the plurality of line sensors L1 and L2 may measure an annular measurement region SR of which width is a measurement width of a line sensor 41.

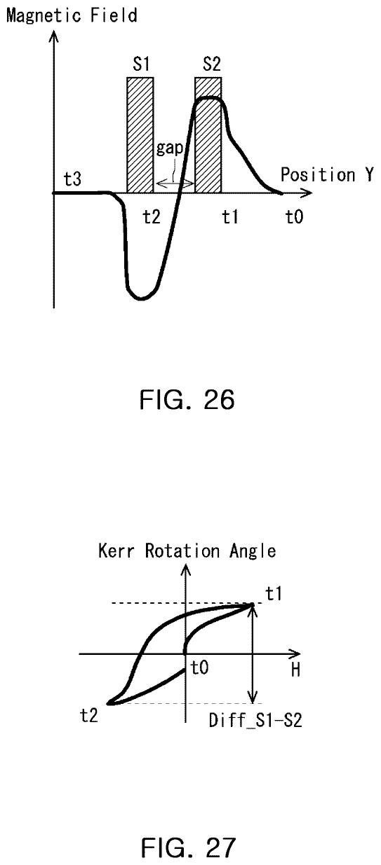

FIG. 26 is a graph illustrating a magnetic field component in a Z-axis direction on a measurement surface Z0 in a device 3a for measuring magnetic characteristics according to modified example 1 of embodiment 3, wherein a horizontal axis represents a position in a Y-axis direction on the measurement surface Z0, and a vertical axis represents the magnetic field component in the Z-axis direction in the measurement surface Z0. FIG. 27 is a graph illustrating a Kerr rotation angle on a measurement surface Z0 in a device 3a for measuring magnetic characteristics according to modified example 1 of embodiment 3, wherein a horizontal axis represents a magnetic field component in a Z-axis direction of an external magnetic field, and a vertical axis represents the Kerr rotation angle.

As illustrated in FIGS. 26 and 27, at time t=t0, an MRAM element may be located in a region in which a magnetic field component in the Z-axis direction is 0. When the MRAM element moves in the +θ direction, an external magnetic field received by the MRAM element may increase. Therefore, a Kerr rotation angle may also increase. The Kerr rotation angle may be saturated when the Kerr rotation angle reaches a certain value, and may not be changed even when the external magnetic field increases (time t=t1). A line sensor L2 may acquire luminance by a Kerr rotation angle of a plurality of MRAM elements aligned side by side in a radial direction at time t=t1.

Further, when the MRAM element moves in the +θ direction, the external magnetic field received by the MRAM element may be reduced. Therefore, the Kerr rotation angle may also be reduced. Furthermore, the external magnetic field may be 0. Furthermore, when the MRAM element moves in the +θ direction, the external magnetic field received by the MRAM element may be reversed. Therefore, the Kerr rotation angle may be reduced. When the MRAM element moves in the +θ direction, the external magnetic field received by the MRAM element in a reverse direction may increase. Therefore, the Kerr rotation angle may be further reduced.

When the external magnetic field in a reverse direction increases at time t-t2, the Kerr rotation angle may be reduced. A line sensor L1 may acquire luminance by a Kerr rotation angle of a plurality of MRAM elements aligned side by side in a radial direction at time t=t2. Furthermore, when the MRAM element moves in the +θ direction, the external magnetic field in a reverse direction received by the MRAM element may be reduced. The external magnetic field may become 0.

As illustrated in FIG. 26, in the present embodiment, the line sensor L2 may obtain the luminance of the plurality of MRAM elements at time t=t1. In addition, the line sensor L1 may obtain the luminance of the plurality of MRAM elements at time t=t2. An information processing unit 50 may detect a difference Diff between luminance of an MRAM element that may be defective at time t=t1 and luminance of an MRAM element that may be defective at time t=t2.

### Modified Example 2

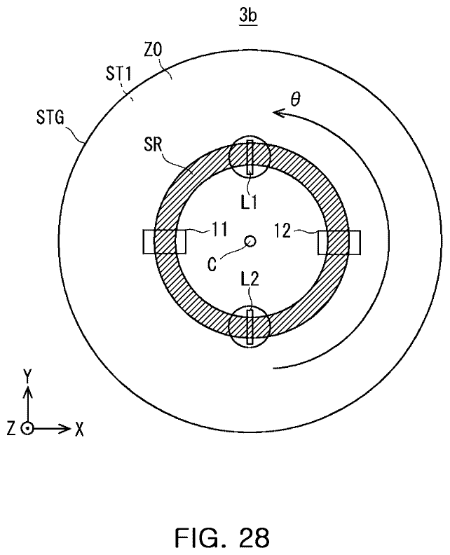

Next, a device for measuring magnetic characteristics according to modified example 2 of embodiment 3 will be described. FIG. 28 is a plan view illustrating arrangement of a stage STG, electromagnets 11 and 12, and line sensors L1 and L2 in a device 3b for measuring magnetic characteristics according to modified example 2 of embodiment 3. As illustrated in FIG. 28, in a device 3b for measuring magnetic characteristics, a center position between an electromagnet 11 and an electromagnet 12 on a stage surface ST1 may be located on a rotation axis C. The electromagnet 11 may be disposed in the −X-axis direction of the rotation axis C, and the electromagnet 12 may be disposed in the +X-axis direction of the rotation axis C. A gradient magnetic field may be formed in the X-axis direction.

A plurality of line sensors L1 and L2 may be disposed in the +Y-axis direction of the rotation axis C and the −Y-axis direction of the rotation axis C. The plurality of line sensors L1 and L2 may extend in the Y-axis direction. The electromagnet 11, the electromagnet 12, the line sensor L1, and the line sensor L2 may be located at an equidistant distance from the rotation axis C. Therefore, the electromagnet 11, the line sensor L1, the electromagnet 12, and the line sensor L2 may be disposed at equal intervals on a circumference centered on the rotation axis. As a stage STG rotates, the plurality of line sensors L1 and L2 may measure an annular measurement region SR of which width is a measurement width of a line sensor 41.

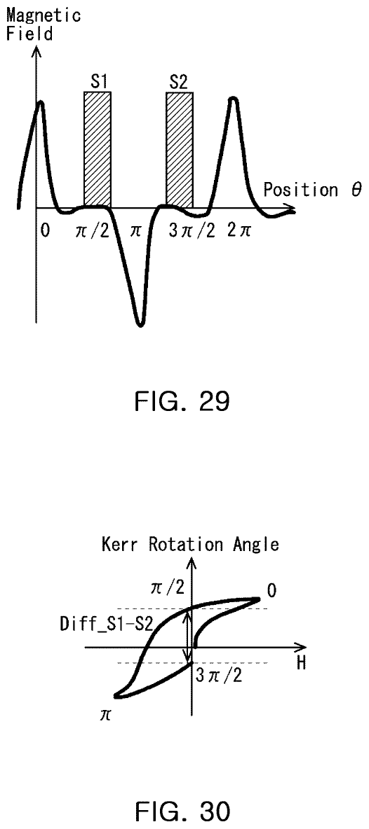

FIG. 29 is a graph illustrating a magnetic field component in a Z-axis direction on a measurement surface Z0 in a device 3b for measuring magnetic characteristics according to modified example 2 of embodiment 3, wherein a horizontal axis represents a position in a measurement region SR expressed by an angle around a rotation axis C, and a vertical axis represents the magnetic field component in the Z-axis direction in the measurement surface Z0. FIG. 30 is a graph illustrating a Kerr rotation angle on a measurement surface Z0 in a device 3b for measuring magnetic characteristics according to modified example 2 of embodiment 3, wherein a horizontal axis represents a magnetic field component in a Z-axis direction of an external magnetic field, and a vertical axis represents the Kerr rotation angle.

As illustrated in FIGS. 29 and 30, at a position of 0-0 on a measurement surface Z0, an MRAM element may be located directly below an electromagnet 12. Therefore, the MRAM element may be located in a region in which a magnetic field component in the +Z-axis direction is large. When the MRAM element moves in the +θ direction, an external magnetic field received by the MRAM element may be reduced. Therefore, a Kerr rotation angle may also be reduced. At θ=π/2, the external magnetic field may become 0. A line sensor L1 may acquire luminance by a Kerr rotation angle of a plurality of MRAM elements aligned side by side in a radial direction at 0=π/2.

Further, when the MRAM element moves in the θ direction, the external magnetic field in a reverse direction received by the MRAM element may increase. Therefore, the Kerr rotation angle may decrease. At 0=T, the MRAM element may be located directly below the electromagnet 11. Therefore, the MRAM element may be located in a region in which a magnetic field component in a reverse direction is large. Furthermore, when the MRAM element moves in the +θ direction, the magnetic field component in a reverse direction received by the MRAM element may decrease. At θ=3π/2, the external magnetic field may become 0. A line sensor L2 may acquire luminance by a Kerr rotation angle of a plurality of MRAM elements aligned side by side in a radial direction at θ=3π/2. An information processing unit 50 may detect a difference Diff between luminance of an MRAM element that may be defective at θ=π/2 and luminance of an MRAM element that may be defective at θ=3π/2.

### Modified Example 3

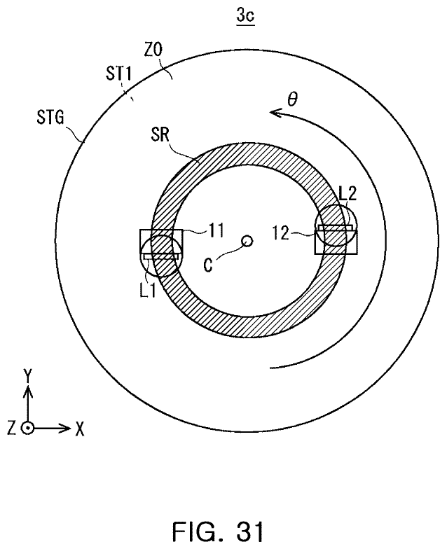

Next, a device for measuring magnetic characteristics according to modified example 3 of embodiment 3 will be described. FIG. 31 is a plan view illustrating arrangement of a stage STG, electromagnets 11 and 12, and line sensors L1 and L2 in a device 3c for measuring magnetic characteristics according to modified example 3 of embodiment 3. As illustrated in FIG. 31, in a device 3c for measuring magnetic characteristics, a center position between an electromagnet 11 and an electromagnet 12 on a stage surface ST1 may be located on a rotation axis C. The electromagnet 11 may be disposed in the −X-axis direction of the rotation axis C, and the electromagnet 12 may be disposed in the +X-axis direction of the rotation axis C. A gradient magnetic field may be formed in the X-axis direction.

A line sensor L1 may be disposed slightly in a +θ direction of the electromagnet 11, and a line sensor L2 may be disposed slightly on the +θ direction of the electromagnet 12. The plurality of line sensors L1 and L2 may extend in the X-axis direction. As a stage STG rotates, the plurality of line sensors L1 and L2 may measure an annular measurement region SR of which width is a measurement width of a line sensor 41.

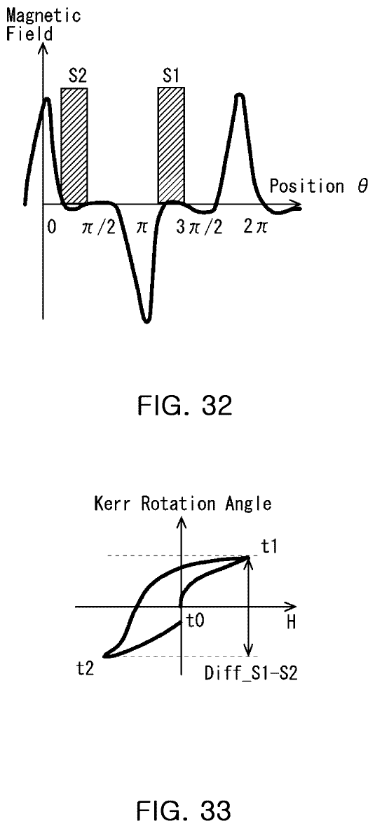

FIG. 32 is a graph illustrating a magnetic field component in a Z-axis direction on a measurement surface Z0 in a device 3c for measuring magnetic characteristics according to modified example 3 of embodiment 3, wherein a horizontal axis represents a position in a measurement region SR expressed by an angle around a rotation axis C, and a vertical axis represents the magnetic field component in the Z-axis direction in the measurement surface Z0. FIG. 33 is a graph illustrating a Kerr rotation angle on a measurement surface Z0 in a device 3c for measuring magnetic characteristics according to modified example 3 of embodiment 3, wherein a horizontal axis represents a magnetic field component in a Z-axis direction of an external magnetic field, and a vertical axis represents the Kerr rotation angle.

As illustrated in FIGS. 32 and 33, at a position of θ=0 on a measurement surface Z0, an MRAM element may be located directly below an electromagnet 12. Therefore, the MRAM element may be located in a region in which a magnetic field component in the +Z-axis direction is large. A line sensor L2 may acquire luminance by a Kerr rotation angle of a plurality of MRAM elements aligned side by side in a radial direction slightly moved in a +θ direction from the electromagnet 12.

When the MRAM element moves further in the +θ direction, an external magnetic field received by the MRAM element may be reduced. Therefore, the Kerr rotation angle may be reduced. At θ=π/2, the external magnetic field may be 0. Furthermore, when the MRAM element moves in the +θ direction, the external magnetic field in a reverse direction received by the MRAM element may increase. Therefore, the Kerr rotation angle may decrease.

At θ=π, the MRAM element may be located directly below an electromagnet 11. Therefore, the MRAM element may be located in a region in which a magnetic field component in a reverse direction is large. A line sensor L1 may acquire luminance by a Kerr rotation angle of a plurality of MRAM elements aligned side by side in a radial directions lightly moved in the +θ direction from the electromagnet 11.

Further, when the MRAM element moves in the +θ direction, the external magnetic field in a reverse direction received by the MRAM element may decrease. At θ=3π/2, the external magnetic field may be 0. An information processing unit 50 may detect a difference Diff between luminance of an MRAM element that may be defective at a position slightly in the +θ direction from θ=0 and luminance of an MRAM element that may be defective at a position slightly in the +θ direction from θ=π. Configurations and effects, different from those described above, in embodiment 3 and modified examples 1 to 3, may be included in the descriptions of embodiments 1 and 2.

In addition, the present inventive concept is not limited to the above-described embodiments, and may be appropriately changed without departing from the spirit thereof. For example, it will be considered that a combination of respective configurations of embodiments 1 to 3 and modified examples 1 to 3 may be also within the scope of the technical idea of the present inventive concept.

According to aspects of the present inventive concept, a device for measuring magnetic characteristics capable of shortening a measurement time period may be provided.

Various advantages and effects of the present inventive concept are not limited to the above-described contents, and will be more easily understood in the process of explaining specific embodiments.

While example embodiments have been illustrated and described above, it will be apparent to those skilled in the art that modifications and variations could be made without departing from the scope of the present inventive concept.

What is claimed is:

1. A device for measuring magnetic characteristics, comprising:
a first magnetic field generator configured to generate a gradient magnetic field having a different magnetic field depending on a position;
a second magnetic field generator configured to generate a high-frequency magnetic field that is time-varying;
a first actuator configured to move the second magnetic field generator;
a mount configured to support a test object mounted thereon;
a second actuator configured to move the mount; and
a measuring unit configured to measure magnetic characteristics of the test object moving in the gradient magnetic field.

2. The device of claim 1, further comprising:
a light source configured to generate light;
a polarizer configured to convert the generated light into linearly polarized light;
an objective lens configured to focus the light on the test object;
a non-polarizing beam splitter configured to separate the light;
an analyzer configured to detect a rotational component in the linearly polarized light of the light; and
a line sensor configured to acquire a scanned image in which the light is scanned on the test object,
wherein the device is configured to measure the magnetic characteristics according to a polarization state of the light.

3. The device of claim 2, wherein the second magnetic field generator comprises a slit disposed between the objective lens and the test object to conduct an optical path between the objective lens and the test object.

4. The device of claim 2, wherein the first magnetic field generator comprises two or more magnet units,
wherein an optical path between the objective lens and the test object is disposed between the two or more magnet units.

5. The device of claim 1, wherein the device executes:
preliminary measurement measuring, in advance, a relationship between a frequency and characteristics of the magnetic field for a sample for preliminary measurement; and
main measurement selecting a predetermined range of the frequency based on the relationship obtained from the preliminary measurement, and measuring the magnetic characteristics of the test object in the predetermined range of the frequency.

6. The device of claim 1, further comprising:
a controller configured to control the first magnetic field generator, the second magnetic field generator, the first actuator, and the second actuator,
wherein the controller is configured to execute:
a first measurement mode in which the magnetic characteristics of the test object are measured by the measuring unit while moving the second magnetic field generator with the first actuator, and moving the mount with the second actuator; and
a second measurement mode in which the magnetic characteristics of the test object are measured by the measuring unit while fixing a position of the second magnetic field generator, and moving the mount with the second actuator.

7. The device of claim 6, wherein the controller is configured to move:
the second magnetic field generator together with the test object with respect to the first magnetic field generator in the first measurement mode, and
the test object with respect to the second magnetic field generator and the first magnetic field generator in the second measurement mode.

8. The device of claim 6, wherein the controller further executes a mode in which a resonance frequency of the test object is measured based on the magnetic characteristics of the test object measured in the first measurement mode, and
in the second measurement mode, the magnetic characteristics of the test object are measured in a frequency range including the resonance frequency.

9. The device of claim 1, wherein the gradient magnetic field is a static magnetic field.

10. The device of claim 1, wherein measurement of the magnetic characteristics is performed under atmospheric conditions.

11. The device of claim 1, further comprising:
a temperature controller configured to control a temperature of the test object.

12. The device of claim 1, further comprising:
a third actuator configured to move the first magnetic field generator.

13. A device for measuring magnetic characteristics, comprising:
a stage configured to support a test object loaded thereon;
a first magnetic field generator installed on the stage, and configured to generate a gradient magnetic field having a different magnetic field intensity depending on a position;
a second magnetic field generator installed on the stage, and configured to generate a high-frequency magnetic field that is time-varying;
a controller configured to move the first magnetic field generator, the second magnetic field generator, and the stage; and
a measuring unit configured to measure the magnetic characteristics of the test object moving in the gradient magnetic field,
wherein the measuring unit is configured to sequentially execute:
a preliminary measurement measuring a relationship between a frequency and a magnetic field, in a state in which a sample is disposed at a standard position defined on a stage surface, which is an upper surface of the stage, and
a main measurement measuring the magnetic characteristics of the test object at a frequency in a predetermined range selected in the preliminary measurement.

14. The device of claim 13, wherein, in the preliminary measurement, a focus between the sample disposed at the standard position and an electric signal probe included in the second magnetic field generator is adjusted, and
the relationship between the frequency and the magnetic field is measured by sweeping the frequency, and executing ferromagnetic resonance (FMR) measurement.

15. The device of claim 13, wherein the frequency in the predetermined range is selected relative to a resonance frequency, based on the relationship between the frequency and the magnetic field, measured in the preliminary measurement.

16. The device of claim 13, wherein, in the main measurement, the magnetic characteristics of the test object is measured by sweeping the frequency in the predetermined range and executing ferromagnetic resonance (FMR) measurement.

17. A device for measuring magnetic characteristics, comprising:
a stage configured to support a test object loaded thereon;
a first magnetic field generator installed in a frame located above the stage and including a plurality of magnet units;
a second magnetic field generator installed between the stage and the frame in a direction perpendicular to a stage surface, which is an upper surface of the stage, and including at least one electric signal probe, and a base supporting the electric signal probe and having a slit adjacent to the electric signal probe in a direction parallel to the stage surface; and
an optical system installed on the frame and configured to radiate incident light to the test object through the slit and collect reflected light reflected from the test object through the slit.

18. The device of claim 17, wherein the second magnetic field generator comprises a first electric signal probe and a second electric signal probe, and the slit is located between the first electric signal probe and the second electric signal probe in a direction parallel to the stage surface.

19. The device of claim 17, wherein the base comprises a dielectric.

20. The device of claim 17, wherein the electric signal probe is disposed on a lower surface of the base, adjacent to the stage.
